(19) United States
(12) Patent Application Publication
(10) Pub. No.: US 2026/0305894 A1
(43) Pub. Date: Oct. 8, 2026

(54) WASTE TAPE RECOVERY DEVICE

(71) Applicant: FUJI CORPORATION, Chiryu (JP)

(72) Inventors: Hidetoshi KAWAI, Anjo-shi (JP); Yoshihiro TAKASHIMA, Chiryu-shi (JP)

(73) Assignee: FUJI CORPORATION, Chiryu (JP)

(21) Appl. No.: 19/483,456

(22) PCT Filed: Jun. 21, 2023
(86) PCT No.: PCT/JP2023/022987

§ 371 Date: Nov. 11, 2025

(51) Int. Cl. A47L 9/14; A47L 9/12; A47L 9/24; A47L 9/28; G01N 21/55

(52) U.S. Cl. CPC A47L 9/149; A47L 9/12; A47L 9/242; A47L 9/2805; G01N 21/55

(57) ABSTRACT

A waste tape recovery device is used while connected to a mounting line configured to take out and mount a component supplied from a tape feeder, and recovers a waste tape after the component is taken out. The device includes a housing, an accommodation box that includes a suction port and an exhaust port, is disposed inside the housing to be taken in and out, and accommodates the waste tape, a waste tape path connected to the suction port, the waste tape passing through the waste tape path, an exhaust path connected to the exhaust port, and a filter provided in the exhaust port.

### TECHNICAL FIELD

The present description discloses a waste tape recovery device.

### BACKGROUND ART

Conventionally, as a waste tape recovery device of this type, there has been known a device which cuts a tape member supplied by a tape feeder and from which a component has been taken out, and recovers the cut tape member (waste tape) in an accommodation box. For example, Patent Literature 1 discloses a waste tape recovery device including a chute portion on which waste tape falls, a waste tape accommodation portion in which a dust box is disposed, a transfer path (tube member) disposed between the chute portion and the waste tape accommodation portion, and a negative pressure application portion that applies a negative pressure from the waste tape accommodation portion side to the transfer path.

### CITATION LIST

### Patent Literature

Patent Literature 1: WO 2017/026030

### BRIEF SUMMARY

### Technical Problem

In a waste tape recovery device of a type in which an accommodation box is disposed inside a housing to be taken in and out and a waste tape is suctioned by a negative pressure and accommodated in the accommodation box, the waste tape may spill out from a gap between the housing and the accommodation box during the waste tape being accommodated in the accommodation box. In this case, when the accommodation box in which the waste tape is accumulated is taken out from the housing and the waste tape is recovered, it is necessary to remove the waste tape spilled into the housing, which increases a burden on a worker.

A main object of the present disclosure is to accommodate a waste tape in an accommodation box without spilling the waste tape in a configuration in which the accommodation box is disposed to be taken in and out inside a housing and the waste tape is suctioned by a negative pressure and accommodated in the accommodation box.

### Solution to Problem

The present disclosure adopts the following means to achieve the above-described main object.

According to the present disclosure, there is provided a waste tape recovery device for use while connected to a mounting line configured to take out and mount a component supplied from a tape feeder, the waste tape recovery device being configured to recover a waste tape after the component is taken out, the waste tape recovery device including:
a housing;
an accommodation box including a suction port and an exhaust port, disposed inside the housing to be taken in and out, and configured to accommodate the waste tape;
a waste tape path connected to the suction port, the waste tape passing through the waste tape path;
an exhaust path connected to the exhaust port; and
a filter provided in the exhaust port.

In the waste tape recovery device of the present disclosure, the suction port and the exhaust port are provided in the accommodation box disposed to be taken in and out inside the housing, the waste tape path is connected to the suction port, and the exhaust path is connected to the exhaust port. The filter is provided in the exhaust port. Accordingly, it is possible to prevent a gap from being generated between the waste tape path and the accommodation box, and it is possible to accommodate the waste tape that has passed through the waste tape path in the accommodation box without spilling.

### BRIEF DESCRIPTION OF DRAWINGS

FIG. 1 is a schematic configuration view of a component mounting line.

FIG. 2 is an external perspective view of the component mounting line and a waste tape recovery device disposed in the component mounting line.

FIG. 3 is a schematic configuration view of a component mounter.

FIG. 4 is a schematic configuration view of a waste tape discharge device.

FIG. 5 is a view illustrating an aspect in which a waste tape is conveyed between adjacent conveyors of a waste tape conveyance device.

FIG. 6 is an external perspective view of the waste tape recovery device.

FIG. 7 is an external perspective view of an accommodation box.

FIG. 8 is a schematic configuration view of a connection portion.

FIG. 9A is a view illustrating an aspect in which a connection duct is connected to a suction port of the accommodation box.

FIG. 9B is a view illustrating an aspect in which the connection duct is connected to the suction port of the accommodation box.

FIG. 10A is an external perspective view of a lever mechanism.

FIG. 10B is a side view of the lever mechanism.

FIG. 11 is a view illustrating a second arrangement example of the waste tape recovery device.

FIG. 12 is a view illustrating a second arrangement example of the connection duct of the connection portion.

### DESCRIPTION OF EMBODIMENTS

Next, embodiments for carrying out the present disclosure will be described with reference to the drawings.

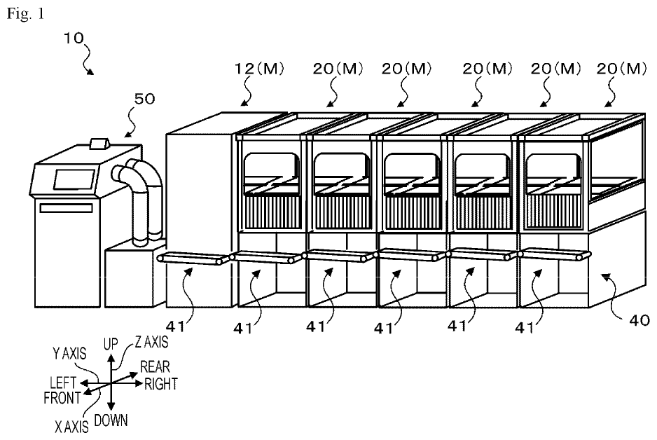

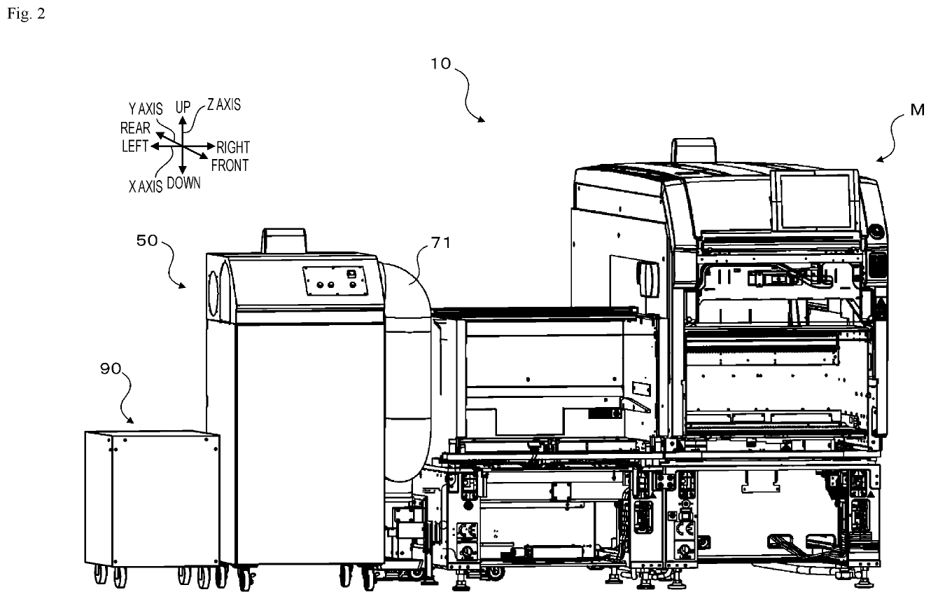

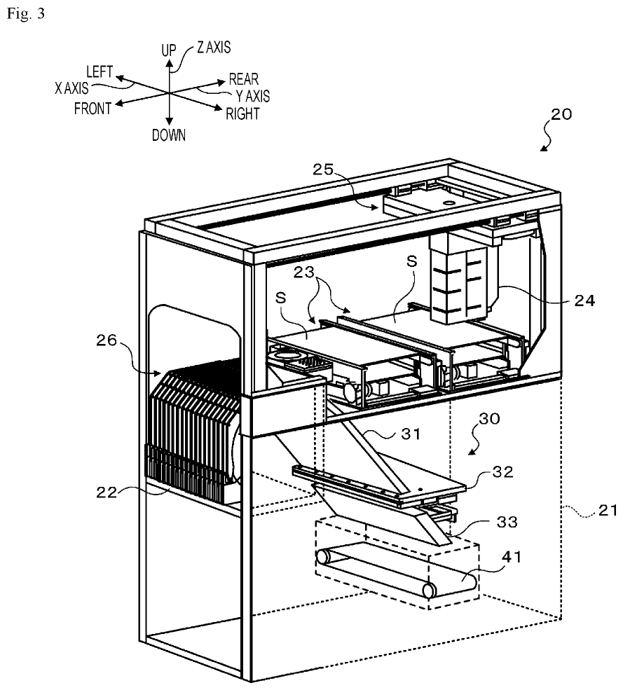

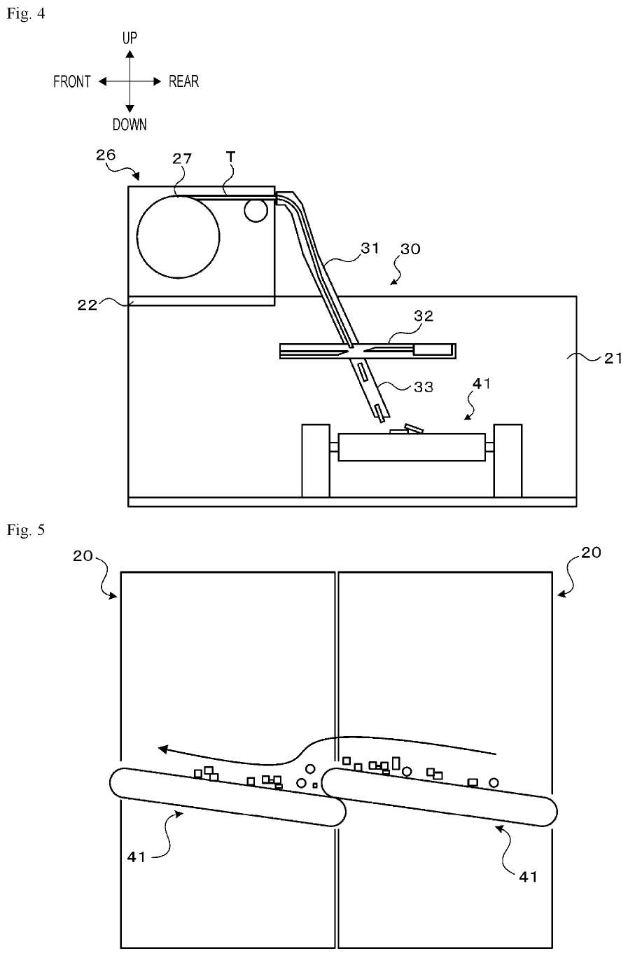

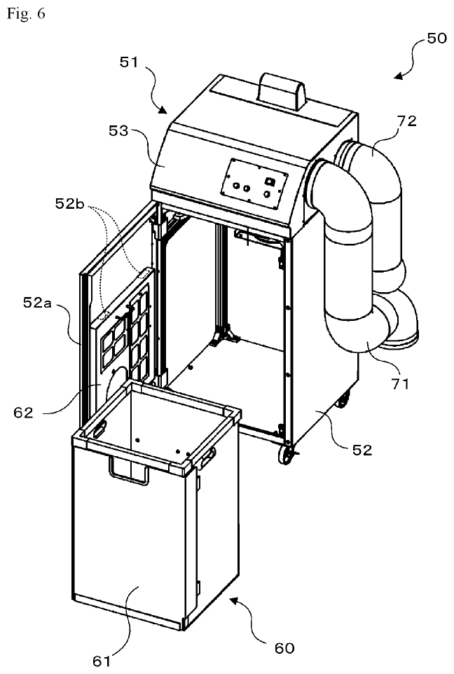

FIG. 1 is a schematic configuration view of component mounting line 10. FIG. 2 is an external perspective view of component mounting line 10 and waste tape recovery device disposed in component mounting line 10. FIG. 3 is a schematic configuration view of component mounter 20. FIG. 4 is a schematic configuration view of waste tape discharge device 30. FIG. 5 is a view illustrating an aspect in which a waste tape is conveyed between adjacent conveyor devices 41 of waste tape conveyance device 40. FIG. 6 is a schematic configuration view of waste tape recovery device 50. Note that in FIGS. 1 to 3, a right-left direction is set as an X-axis direction, a front-rear direction is set as a Y-axis direction, and an up-down direction is set as a Z-axis direction.

As illustrated in FIG. 1, component mounting line 10 includes printer 12, multiple component mounters 20, and waste tape conveyance device 40. Printer 12 is a solder printer for printing solder on board S. Component mounters 20 are aligned along a board conveyance direction (X direction) to mount a component on board S. In component mounting line 10, printer 12 and component mounter 20 are disposed in this order in the board conveyance direction. Note that hereinafter, each device constituting component mounting line 10 may be referred to as module M.

As illustrated in FIG. 3, component mounter 20 includes housing 21, feeder base 22, board conveyance device 23, head 24, and head moving mechanism 25. Multiple feeder bases 22 are aligned in the X direction and detachably hold feeder 26. Board conveyance device 23 is a belt conveyor device and conveys board S from left to right. Head 24 holds a suction nozzle, picks up component P supplied from feeder 26 mounted on feeder base 22 by the suction nozzle, and mounts component P on board S. Head moving mechanism 25 moves head 24 between feeder 26 and board S.

As illustrated in FIG. 4, feeder 26 includes reel 27 on which tape T is wound. Tape T has cavities (recessed portions) arranged at predetermined intervals in a longitudinal direction, and components P are accommodated in the cavities. Components P are protected by a cover film attached to an upper surface of tape T. Feeder 26 supplies components P to a pickup position in an exposed state by pulling out tape T from reel 27 by a feeding device (not illustrated) and peeling the cover film from tape T. Component P supplied to the pickup position is taken out by the suction nozzle. The used tape after component P is taken out by the suction nozzle is discharged by waste tape discharge device 30.

As illustrated in FIG. 3, waste tape discharge device 30 includes introduction duct 31 that introduces the tape fed from feeder 26 provided behind feeder 26 mounted on feeder base 22, tape cutter 32 that finely cuts the introduced tape by a cutter, and discharge duct 33 that discharges the cut tape (hereinafter, referred to as a waste tape). Whenever feeder 26 feeds tape T for supply of component P, tape cutter 32 cuts the tape by driving the cutter. The waste tape is supplied to conveyor device 41 through discharge duct 33 and conveyed to the outside of component mounter 20 by conveyor device 41. The waste tape conveyed to the outside of component mounter 20 is recovered by waste tape recovery device 50 of the present embodiment.

Waste tape conveyance device 40 includes conveyor device 41. Conveyor device 41 is provided for each module M. When modules M constitute component mounting line 10, conveyor devices 41 are aligned in a row in the board conveyance direction. As illustrated in FIG. 5, each conveyor device 41 is installed to be inclined upward toward a waste tape conveyance direction and is configured such that end portions of adjacent conveyor devices 41 vertically overlap each other. Thus, each conveyor device 41 can smoothly convey the waste tape to adjacent conveyor device 41 and prevent the waste tape from falling during the conveyance. In the present embodiment, the waste tape conveyance direction is set to a direction opposite to the board conveyance direction (upstream direction of the component mounting line), but may be set to the same direction as the board conveyance direction.

Each conveyor device 41 is controlled by a control device provided in corresponding module M. The control device controls entire corresponding module M in addition to conveyor device 41. For example, the control device that controls component mounter 20 as module M controls board conveyance device 23, head 24, or head moving mechanism 25 in addition to conveyor device 41.

As illustrated in FIG. 1, waste tape recovery device 50 is installed to be adjacent to module M at a starting end in the board conveyance direction, and suctions and recovers the waste tape conveyed by waste tape conveyance device 40 by a negative pressure. As illustrated in FIG. 6, waste tape recovery device 50 includes recovery device main body 51, accommodation box 60, suction hose 71, exhaust hose 72, and negative pressure source 90 (refer to FIG. 2).

As illustrated in FIG. 6, recovery device main body 51 is a box-shaped housing, and includes accommodation portion 52 having an opening in a front surface and an accommodation space to and from which accommodation box 60 can be taken in and out through the opening, and connection portion 53 to which suction hose 71 and exhaust hose 72 are connected. Accommodation portion 52 is provided in a lower portion of recovery device main body 51, and connection portion 53 is provided in an upper portion of recovery device main body 51.

Opening door 52a that can be opened and closed with a left side as a rotation axis is attached to the front surface of accommodation portion 52. Accommodation box 60 is taken in and out with respect to accommodation portion 52 in a state in which opening door 52a is opened. When opening door 52a is closed, the inside of recovery device main body 51 is sealed.

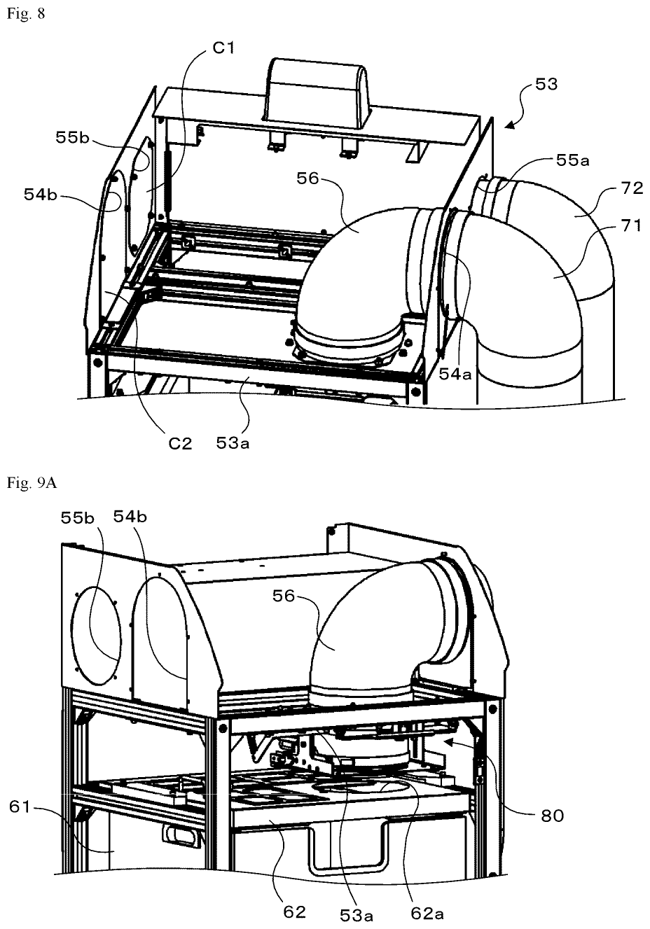

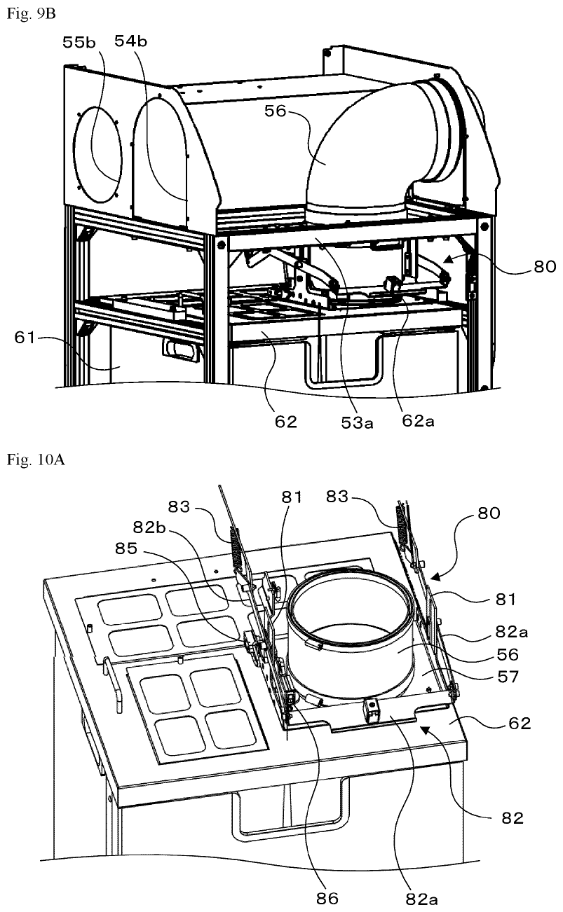

As illustrated in FIGS. 8, 9A, and 9B, connection portion 53 includes suction hose connection ports 54a and 54b to which a first end portion of suction hose 71 is connected, exhaust hose connection ports 55a and 55b to which a first end portion of exhaust hose 72 is connected, bellows-shaped connection duct 56 of which a first end portion is detachable from any of suction hose connection ports 54a and 54b and can be expanded and contracted, and lever mechanism 80 for attaching and detaching a second end portion of connection duct 56 to and from accommodation box 60 accommodated in recovery device main body 51 (accommodation portion 52). A second end portion of suction hose 71 is disposed at a conveyance end of each of conveyor devices 41 aligned in a row. A second end portion of exhaust hose 72 is connected to negative pressure source 90.

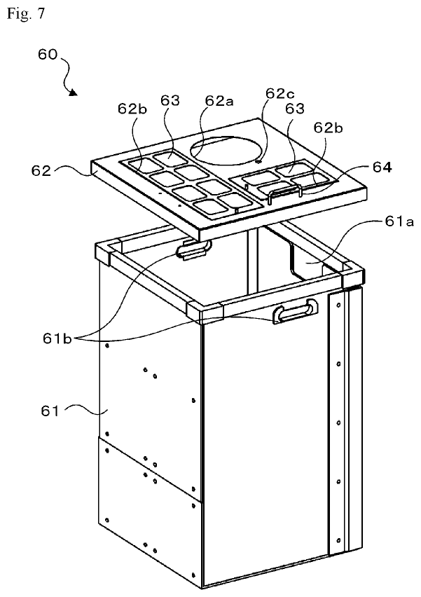

Accommodation box 60 is a box for storing waste tape. As illustrated in FIG. 7, accommodation box 60 includes box-shaped box main body 61 in which an upper end is opened, and lid member 62 that closes the opening of the upper end of box main body 61. Handle hole 61a for a worker to take out accommodation box 60 from recovery device main body 51 (accommodation portion 52) is formed in a front upper portion of box main body 61. In addition, handle holes 61b for the worker to carry box main body 61 are formed in upper right and left side surfaces of box main body 61.

Suction port 62a and exhaust port 62b are formed in lid member 62. Suction port 62a is a circular opening, and the second end portion of connection duct 56 is attached to and detached from suction port 62a. Connection duct 56 is mounted on suction port 62a to cause the inside of suction hose 71 to communicate with the inside of accommodation box 60. Exhaust port 62b is an opening larger than suction port 62a formed at a position avoiding suction port 62a, and exhaust port 62b is covered with filter 63. An internal space of connection portion 53 is partitioned between the inside and the outside of connection duct 56, and connection portion 53 causes exhaust hose 72 and the inside of accommodation box 60 to communicate with each other by a space outside connection duct 56 in the internal space of connection portion 53. Note that lid member 62 is provided with handle 64 for the worker to remove lid member 62 from accommodation box 60 and carry lid member 62. On a rear surface of opening door 52a of recovery device main body 51, hook member 52b is provided as a temporary placement portion. Lid member 62 removed from accommodation box 60 during the worker taking out waste tape accumulated in box main body 61 is hooked on hook member 52b.

As illustrated in FIGS. 9A and 9B, lever mechanism 80 is an operation member that manually lifts and lowers coupling frame 56a provided at the second end portion of bellows-shaped connection duct 56. Coupling frame 56a is coupled to suction port 62a of accommodation box 60 by being lowered to a lower end by lever mechanism 80 in a state in which accommodation box 60 is accommodated in accommodation portion 52. Coupling frame 56a is detached from suction port 62a of accommodation box 60 by being lifted by lever mechanism 80.

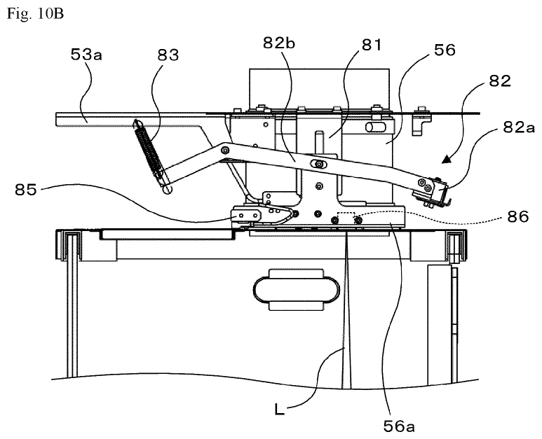

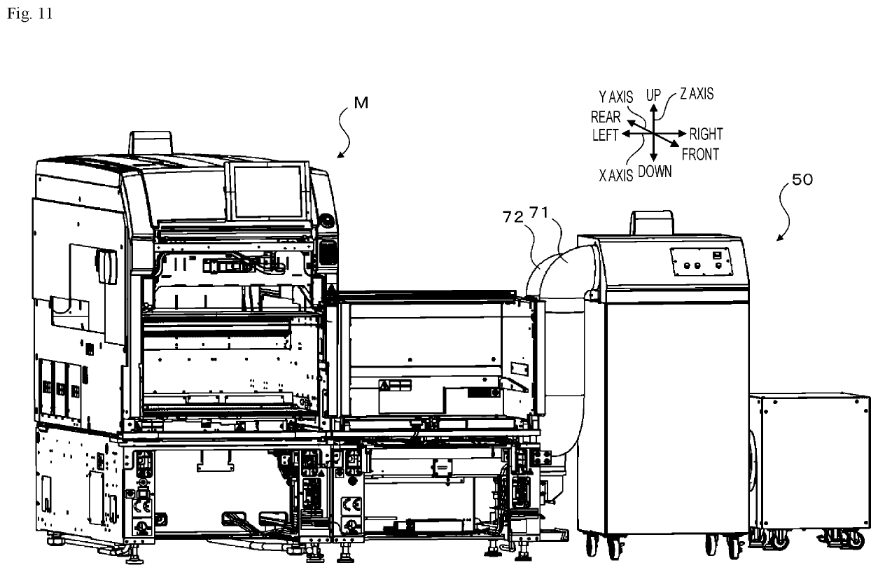

As illustrated in FIGS. 10A and 10B, lever mechanism 80 includes pair of guide members 81, lever main body 82, and attachment/detachment sensing sensor 85. Pair of guide members 81 are fixed to connection portion frame 53a which is a frame body of connection portion 53, and guide coupling frame 56a to be lifted and lowered. Lever main body 82 is a substantially U-shaped member and includes base portion 82a serving as a handle and pair of leg portions 82b bent and extending from both end portions of base portion 82a. Central portions of pair of leg portions 82b in an extending direction are rotatably coupled to coupling frame 56a with a slight play. Tip end portions of pair of leg portions 82b are coupled to connection portion frame 53a via springs 83. Further, the tip end portions and the central portions of pair of leg portions 82b are directly rotatably coupled to connection portion frame 53a. Accordingly, the worker can couple coupling frame 56a to suction port 62a by lowering coupling frame 56a of connection duct 56 by gripping and pushing down base portion 82a (handle). In addition, the worker can detach the coupling frame 56a from suction port 62a by lifting coupling frame 56a of connection duct 56 by gripping and pulling up base portion 82a. Attachment/detachment sensing sensor 85 is fixed to coupling frame 56a and senses attachment and detachment of coupling frame 56a to and from suction port 62a. For example, a proximity sensor such as a magnetic sensor is used as attachment/detachment sensing sensor 85.

Accumulation amount sensing sensor 86 that senses the amount of the waste tape accumulated in accommodation box 60 is also fixed to coupling frame 56a. Accumulation amount sensing sensor 86 is configured as a reflective optical sensor including a light emitting section that emits light L downward into box main body 61 through opening 62c (refer to FIG. 7) formed in lid member 62 adjacent to suction port 62a, and a light receiving section that receives reflected light from a sensing target (waste tape) in box main body 61. Accumulation amount sensing sensor 86 (optical sensor) senses the accumulation amount of the waste tape by measuring time until light L from the light emitting section is reflected by a surface of the waste tape accumulated in box main body 61 and received by the light receiving section.

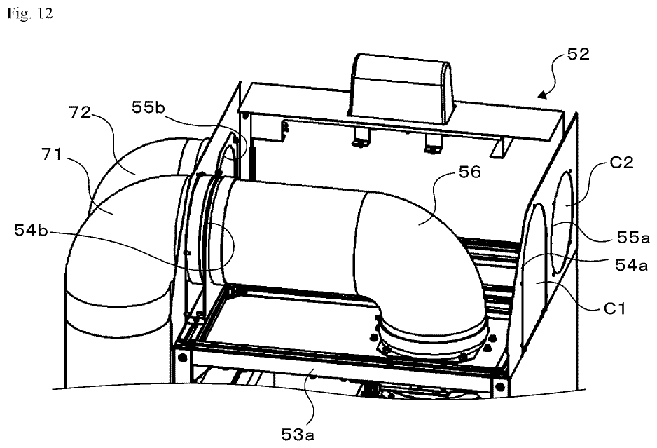

Suction hose connection port 54a and exhaust hose connection port 55a are provided in a right side surface of connection portion 53 (housing), and similar suction hose connection port 54b and exhaust hose connection port 55b are also provided in a left side surface of connection portion 53. Therefore, as illustrated in FIG. 2, when waste tape recovery device 50 is disposed on the left side when component mounting line 10 is viewed from the front, the worker closes suction hose connection port 54b and exhaust hose connection port 55b in the left side surface with lids C1 and C2 and connects a first end portion of connection duct 56 to suction hose connection port 54a in the right side surface as illustrated in FIG. 8. Then, the worker connects suction hose 71 to suction hose connection port 54a and connects exhaust hose 72 to exhaust hose connection port 55a. On the other hand, as illustrated in FIG. 11, when waste tape recovery device 50 is disposed on the right side when component mounting line 10 is viewed from the front, the worker closes suction hose connection port 54a and exhaust hose connection port 55a in the right side surface with lids C1 and C2 and connects the first end portion of connection duct 56 to suction hose connection port 54b in the left side surface as illustrated in FIG. 12. Then, the worker connects suction hose 71 to suction hose connection port 54b and connects exhaust hose 72 to exhaust hose connection port 55b. Accordingly, regardless of the arrangement of waste tape recovery device 50 with respect to component mounting line 10, suction hose 71 and exhaust hose 72 can be connected to recovery device main body 51 without extending a hose length, and the degree of freedom in the arrangement of waste tape recovery device 50 can be secured.

In addition, negative pressure source 90 is controlled by a control device (not illustrated) of waste tape recovery device 50. The control device is configured as a microprocessor mainly including a CPU, and includes a ROM, a RAM, an input/output port, and a communication port in addition to the CPU. A sensing signal from attachment/detachment sensing sensor 85 and a sensing signal from accumulation amount sensing sensor 86 are input to the control device via the input port. The control device outputs a control signal to negative pressure source 90 via the output port. In addition, the control device of waste tape recovery device 50 communicates with the control device of component mounting line 10 via the communication port, and exchanges various signals with the control device of component mounting line 10.

When attachment/detachment sensing sensor 85 does not sense that connection duct 56 is mounted on suction port 62a or when accumulation amount sensing sensor 86 senses that accommodation box 60 is fully filled with the waste tape, the control device of waste tape recovery device 50 stops negative pressure source 90 and transmits a stop signal to the control device of component mounting line 10 to stop the conveyance of the waste tape. Accordingly, it is possible to prevent the waste tape from overflowing in waste tape recovery device 50.

Here, a correspondence relationship between the elements of the embodiment and the elements described in the scope of the claims will be described. That is, component mounting line 10 of the present embodiment corresponds to a mounting line of the present disclosure, recovery device main body 51 corresponds to a housing, accommodation box 60 corresponds to an accommodation box, suction hose 71 corresponds to a waste tape path, exhaust hose 72 corresponds to an exhaust path, and filter 63 corresponds to a filter. Box main body 61 corresponds to a box main body, and lid member 62 corresponds to a lid member. Opening door 52a corresponds to a door, and hook member 52b corresponds to a temporary placement portion. Suction hose connection ports 54a and 54b correspond to suction connection ports, exhaust hose connection ports 55a and 55b correspond to exhaust connection ports, and connection duct 56 corresponds to a connection pipe. Lever mechanism 80 corresponds to a lever mechanism. Attachment/detachment sensing sensor 85 corresponds to a connection sensing section. Accumulation amount sensing sensor 86 corresponds to an accumulation sensing section.

Note that needless to say, the present disclosure is not limited to the embodiment that has been described heretofore in any way and may be implemented in various forms without departing from the technical scope of the present disclosure.

For example, in the above-described embodiment, connection portion 53 of recovery device main body 51 is provided with two suction hose connection ports 54a and 54b and two exhaust hose connection ports 55a and 55b. However, the number of suction hose connection ports may be one or three or more. The number of exhaust hose connection ports may be one or three or more.

In the above-described embodiment, waste tape recovery device 50 (recovery device main body 51, negative pressure source 90) is disposed adjacent to component mounting line 10. However, recovery device main body 51 may be disposed at a position away from component mounting line 10 by extending suction hose 71. Negative pressure source 90 may be disposed at a position away from component mounting line 10 by extending exhaust hose 72.

In the above-described embodiment, waste tape recovery device 50 suctions and recovers the waste tape conveyed by waste tape conveyance device 40 by a negative pressure, but instead of connecting a conveyance end of conveyor device 41 to suction hose 71, the conveyance end may be directly connected to connection duct 56 of recovery device main body 51 without providing suction hose 71. In this way, even when it is difficult to supply a negative pressure, the waste tape can be recovered in the waste tape recovery device as long as a space for installing a conveyor device can be secured.

As described above, in the waste tape recovery device of the present disclosure, the suction port and the exhaust port are provided in the accommodation box disposed to be taken in and out inside the housing, the waste tape path is connected to the suction port, and the exhaust path is connected to the exhaust port. The filter is provided in the exhaust port. Accordingly, it is possible to prevent a gap from being generated between the waste tape path and the accommodation box, and it is possible to accommodate the waste tape that has passed through the waste tape path in the accommodation box without spilling.

In the waste tape recovery device of the present disclosure, the accommodation box may include a box main body having an opening and a lid member detachably attached to the opening of the box main body, and the suction port and the exhaust port may be provided in the lid member. In this case, since it is not necessary to provide an intake port or an exhaust port in the box main body, it is possible to secure a sufficient accommodation capacity of the waste tape in the box main body. In this case, the housing may include an openable and closable door, and is configured to allow the accommodation box to be taken in and out in a state in which the door is opened, and the door may be provided with a temporary placement portion where the lid member is temporarily placed. With this configuration, when the worker removes the lid member from the accommodation box and takes out the waste tape accumulated in the box main body, it is possible to secure a temporary placement place of the lid member without providing a separate space.

In the waste tape recovery device of the present disclosure, the housing may include a suction connection port to which the waste tape path is connected, and an extendable connection pipe of which a first end is connected to the suction connection port, and a second end of the connection pipe may be detachable from the suction port of the accommodation box disposed inside the housing. With this configuration, the waste tape path can communicate with the inside of the accommodation box by mounting the second end of the connection pipe on the suction port. In this case, the housing may further include an exhaust connection port to which a first end of the exhaust path is connected, the negative pressure source may be connected to a second end of the exhaust path, the exhaust path may be connected to the exhaust connection port to supply a negative pressure generated by the negative pressure source to the accommodation box, the waste tape path may be connected to the suction connection port to supply the negative pressure generated by the negative pressure source from the accommodation box to the mounting line, and at least the suction connection port of the suction connection port and the exhaust connection port may be provided at multiple locations of the housing. In this way, the waste tape path can be connected to the housing with an appropriate path length regardless of the arrangement of the waste tape recovery device with respect to the mounting line, and the degree of freedom in the arrangement of the waste tape recovery device can be secured. In these cases, the housing may include a lever mechanism that attaches and detaches the second end of the connection pipe to and from the suction port of the accommodation box disposed inside the housing. In this way, it is possible to improve efficiency when attaching and detaching the connection pipe. In these cases, a connection sensing section configured to sense a connection between the connection pipe and the suction port may be provided, and the recovery operation may be performed on condition that the connection between the connection pipe and the suction port is sensed by the connection sensing section. Thus, the waste tape can be more reliably accommodated in the accommodation box Further, in the waste tape recovery device of the present disclosure, the waste tape recovery device may further include an accumulation sensing section configured to sense an accumulation state of the waste tape in the accommodation box, and the accumulation sensing section may be a reflective sensor provided such that an optical axis passes through an opening of the accommodation box disposed in the housing. In this way, it is possible to sense the accumulation state of the waste tape in the accommodation box without providing a sensor in the accommodation box.

### INDUSTRIAL APPLICABILITY

The present disclosure is applicable to a manufacturing industry of a waste tape recovery device and a mounting line.

### REFERENCE SIGNS LIST

10: component mounting line, 12: printer, 20: component mounter, 21: housing, 22: feeder base, 23: board conveyance device, 24: head, 25: head moving mechanism, 26: feeder, 27: reel, 30: waste tape discharge device, 31: introduction duct, 32: tape cutter, 33: discharge duct, 40: waste tape conveyance device, 41: conveyor device, 50: waste tape recovery device, 51: recovery device main body, 52: accommodation portion, 52a: opening door, 52b: hook member, 53: connection portion, 53a: connection portion frame, 54a, 54b: suction hose connection port, 55a, 55b: exhaust hose connection port, 56: connection duct, 56a: coupling frame, 60: accommodation box, 61: box main body, 61a, 61b: handle hole, 62: lid member, 62a: suction port, 62b: exhaust port, 62c: opening, 63: filter, 64: handle, 71: suction hose, 72: exhaust hose, 80: lever mechanism, 81: guide member, 82: lever main body, 82a: base portion, 82b: leg portion, 83: spring, 85: attachment/detachment sensing sensor, 86: accumulation amount sensing sensor, 90: negative pressure source, L: light, M: module, P: component, S: board, T: tape.

1. A waste tape recovery device for use while connected to a mounting line configured to take out and mount a component supplied from a tape feeder, the waste tape recovery device being configured to recover a waste tape after the component is taken out, the waste tape recovery device comprising:
a housing;
an accommodation box including a suction port and an exhaust port, disposed inside the housing to be taken in and out, and configured to accommodate the waste tape;
a waste tape path connected to the suction port, the waste tape passing through the waste tape path;
an exhaust path connected to the exhaust port; and
a filter provided in the exhaust port.

2. The waste tape recovery device according to claim 1,
wherein the accommodation box includes a box main body having an opening and a lid member detachably attached to the opening of the box main body, and
the suction port and the exhaust port are provided in the lid member.

3. The waste tape recovery device according to claim 2,
wherein the housing includes an openable and closable door, and is configured to allow the accommodation box to be taken in and out in a state in which the door is opened, and
the door is provided with a temporary placement portion where the lid member is temporarily placed.

4. The waste tape recovery device according to claim 1,
wherein the housing includes a suction connection port to which the waste tape path is connected, and an extendable connection pipe of which a first end is connected to the suction connection port, and
a second end of the connection pipe is detachable from the suction port of the accommodation box disposed inside the housing.

5. The waste tape recovery device according to claim 4,
wherein the housing further includes an exhaust connection port to which a first end of the exhaust path is connected,
a negative pressure source is connected to a second end of the exhaust path,
the exhaust path is connected to the exhaust connection port to supply a negative pressure generated by the negative pressure source to the accommodation box,
the waste tape path is connected to the suction connection port to supply the negative pressure generated by the negative pressure source from the accommodation box to the mounting line, and
at least the suction connection port of the suction connection port and the exhaust connection port is provided at multiple locations of the housing.

6. The waste tape recovery device according to claim 4, wherein the housing includes a lever mechanism configured to attach and detach the second end of the connection pipe to and from the suction port of the accommodation box disposed inside the housing.

7. The waste tape recovery device according to claim 4, further comprising:
a connection sensing section configured to sense a connection between the connection pipe and the suction port,
wherein a recovery operation is performed on condition that the connection between the connection pipe and the suction port is sensed by the connection sensing section.

8. The waste tape recovery device according to claim 1, further comprising:
an accumulation sensing section configured to sense an accumulation state of the waste tape in the accommodation box,
wherein the accumulation sensing section is a reflective sensor provided such that an optical axis passes through an opening of the accommodation box disposed in the housing.
